(19) United States
(12) Patent Application Publication
(10) Pub. No.: US 2025/0010429 A1
(43) Pub. Date: Jan. 9, 2025

(54) LOAD ADJUSTING SYSTEM AND LOAD ADJUSTING METHOD

(71) Applicant: EBARA CORPORATION, Tokyo (JP)

(72) Inventor: Hiroyuki TAKENAKA, Tokyo (JP)

(21) Appl. No.: 18/708,512

(22) PCT Filed: Nov. 4, 2022
(86) PCT No.: PCT/JP2022/041160

§ 371 Date: May 8, 2024

(30) Foreign Application Priority Data
Nov. 10, 2021 (JP) 2021-183206

(51) Int. Cl. B24B 51/00; B24B 9/00

(52) U.S. Cl. CPC B24B 51/00; B24B 9/00

(57) ABSTRACT

A load adjusting system includes: a bevel grinding device including a grinding head configured to grind a bevel part of a substrate; and a control device, the control device is configured to: acquire, from a load measuring device that performs measurement of a pressing load applied from the grinding head, measurement data acquired by performing the measurement; calculate, based on the measurement data and based on a set parameter set for the grinding head, an adjustment value used for adjusting the pressing load; and control a pressing operation of the grinding head based on the adjustment value.

### TECHNICAL FIELD

The present invention relates to a load adjusting system and a load adjusting method.

### BACKGROUND ART

Conventionally, in a bevel grinding device that grinds the bevel part of a substrate, such as a wafer, the grinding amount and the shape of the substrate are controlled by pushing a pad, which is referred to as a grinding pad or a pressurizing pad, against the bevel part of the substrate at an appropriate load with a grinding tape interposed therebetween.

In installing a bevel grinding device or in performing maintenance, it is necessary to perform adjustment such that a bevel part is pressed by a grinding pad at an appropriate load. In such an adjustment work, a load measuring device is mounted on the bevel grinding device to measure the pressing load of the grinding pad by the load measuring device (see PTL 1).

### CITATION LIST

### Patent Literature

PTL 1: Japanese Patent Application Publication No. 2017-94480

### SUMMARY OF INVENTION

### Technical Problem

In performing load adjustment work for the above-described bevel grinding device, cumbersome operations are required, such as an operation where a worker visually reads information about the pressing load of the grinding pad, which is acquired by the load measuring device, and then inputs the information into the bevel grinding device.

The present invention has been made in view of the above-mentioned circumstances, and it is an object of the present invention to efficiently perform load adjustment for a bevel grinding device.

### Solution to Problem

According to one embodiment of the present invention, a load adjusting system comprises: a bevel grinding device comprising a grinding head configured to grind a bevel part of a substrate; and a control device, the control device is configured to: acquire, from a load measuring device that performs measurement of a pressing load applied from the grinding head, measurement data acquired by performing the measurement; calculate, based on the measurement data and based on a set parameter set for the grinding head, an adjustment value used for adjusting the pressing load; and control a pressing operation of the grinding head based on the adjustment value.

According to another embodiment of the present invention, a load adjusting method is a load adjusting method for a bevel grinding device, the load adjusting method comprising: acquiring, from a load measuring device that performs measurement of a pressing load applied from a grinding head, measurement data acquired by performing the measurement; calculating, based on the measurement data and based on a set parameter set for the grinding head, an adjustment value used for adjusting the pressing load; and controlling a pressing operation of the grinding head based on the adjustment value, the acquiring, the calculating, and the controlling being performed by a control device configured to control the bevel grinding device comprising the grinding head configured to grind a bevel part of a substrate.

### BRIEF DESCRIPTION OF DRAWINGS

FIG. 1 is a plan view schematically showing a load adjusting system according to one embodiment of the present invention.

FIG. 2 is a plan view schematically showing a grinding device according to the above-mentioned embodiment.

FIG. 3 is a cross-sectional view schematically showing an example of the internal structures of a grinding head assembly and a tape supply and recovery mechanism in the above-mentioned embodiment.

FIG. 4 is a diagram illustrating an example of a pressurizing mechanism of a grinding head according to the above-mentioned embodiment.

FIG. 5 is an upper perspective view of a load measuring device in the above-mentioned embodiment.

FIG. 6 is a lower perspective view of the load measuring device in the above-mentioned embodiment.

FIG. 7 is a side cross-sectional view of the load measuring device in the above-mentioned embodiment.

FIG. 8 is a side view of the load measuring device in the above-mentioned embodiment as viewed from the grinding head side.

FIG. 9 is a conceptual view showing the configuration of the load adjusting system according to the above-mentioned embodiment.

FIG. 10 is a conceptual view showing an example of a display screen according to the above-mentioned embodiment.

FIG. 11 is a flowchart showing the flow of a load adjusting method according to the above-mentioned embodiment.

FIG. 12A is a diagram showing a use state of the load measuring device according to the above-mentioned embodiment.

FIG. 12B is a diagram showing a use state of the load measuring device according to the above-mentioned embodiment.

FIG. 13 is a conceptual view showing the configuration of a load adjusting system according to a modification 1.

FIG. 14 is a flowchart showing the flow of a load adjusting method according to the modification 1.

FIG. 15 is a side cross-sectional view schematically showing a load measuring device according to a modification 2.

FIG. 16 is a diagram showing an example of image photographed in the modification 2.

FIG. 17 is a conceptual view showing the configuration of a load adjusting system according to the modification 2.

FIG. 18 is a flowchart showing the flow of a load adjusting method according to the modification 2.

FIG. 19 is a conceptual view showing a bevel part of a substrate.

### DESCRIPTION OF EMBODIMENTS

Hereinafter, embodiments of the present invention will be described with reference to drawings. In the drawings described below, identical or corresponding components are given the same reference symbols, and the repeated description will be omitted.

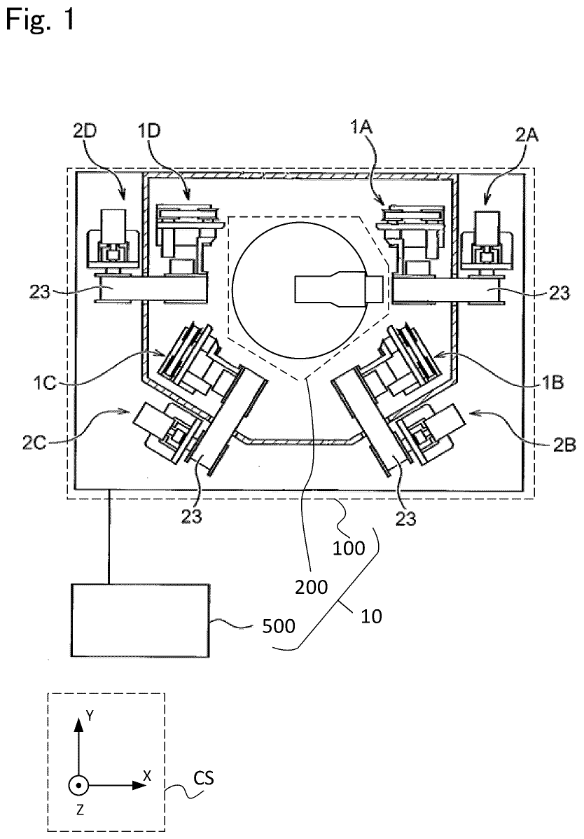

FIG. 1 is a plan view schematically showing a load adjusting system according to the present embodiment. A load adjusting system 10 includes a grinding device 100, a load measuring device 200, and an information processor 500. The grinding device 100 includes grinding head assemblies 1A, 1B, 1C, 1D and tape supply and recovery mechanisms 2A, 2B, 2C, 2D. FIG. 1 shows an example of an arrangement for which, in performing the load adjustment for the grinding device 100, the load measuring device 200 measures the pressing load of the grinding head assembly 1A via a grinding tape 23.

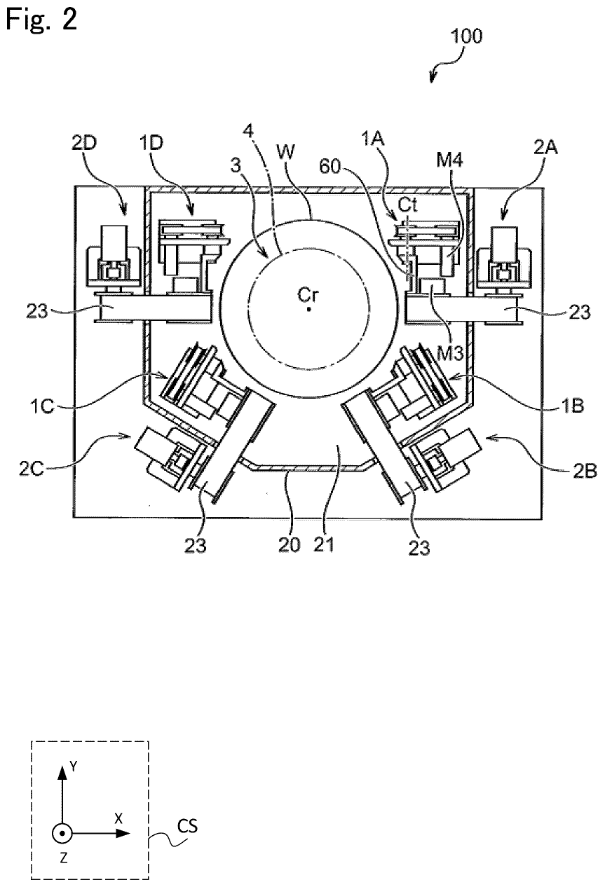

In the following embodiment, a Z axis is taken along a vertical direction, an X axis is taken along a direction in which the grinding head assembly 1A horizontally faces a center axis Cr of a rotationally holding mechanism 3 (see FIG. 2), and a Y axis is taken along a direction perpendicular to the Z axis and the X axis (see a coordinate system CS).

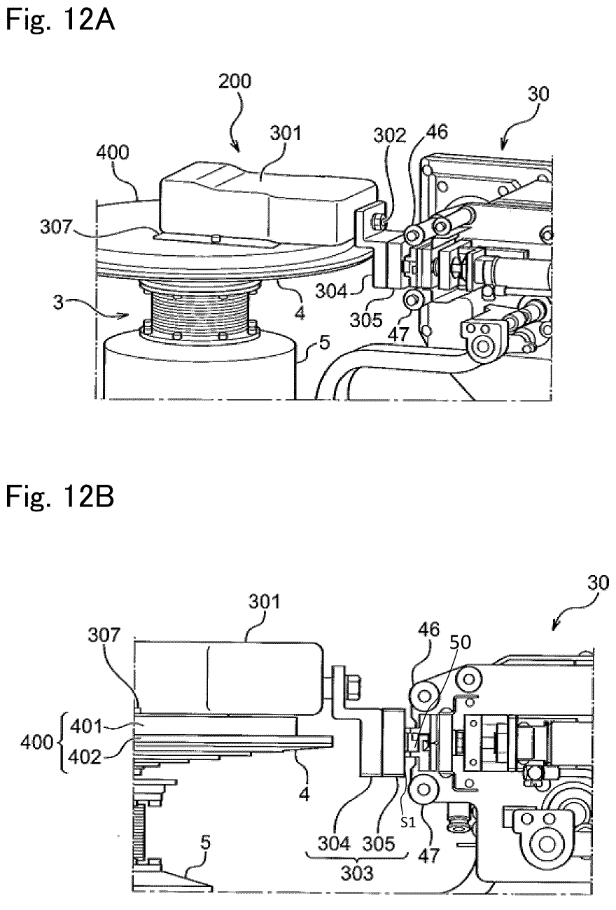

FIG. 2 is a plan view schematically showing the grinding device 100. FIGS. 2 to 4 show the arrangement of respective components when the grinding device 100 grinds a substrate W. The rotationally holding mechanism 3 is provided at the center portion of the grinding device 100, the rotationally holding mechanism 3 horizontally holding and rotating the substrate W, such as a wafer, being an object to be ground. To be more specific, the rotationally holding mechanism 3 includes a vacuum suction table 4 and a shaft 5 (see FIG. 12A), the vacuum suction table 4 holding the rear surface of the substrate W by vacuum suction, the shaft 5 being mounted at the center portion of the vacuum suction table 4. The shaft 5 is rotated by a motor not shown in the drawing in such a way as to cause the substrate W to rotate about the center axis Cr of the vacuum suction table 4. The vacuum suction table 4 and the shaft 5 have a vacuum passage into which a negative pressure is introduced to suction the substrate W onto the vacuum suction table 4.

The grinding device 100 grinds the bevel part of the substrate W, such as a wafer. FIG. 19 is a side view of the substrate W, and is also a diagram showing the peripheral edge part of the substrate W in an enlarged manner. In FIG. 19, semiconductor devices or the like are formed at a flat part D of the substrate W, and the flat part D is located at a position several millimeters inward from an end surface G. Semiconductor devices or the like are not formed in a flat part E disposed outward of the region D. In this DESCRIPTION, a region B extending from an upper inclined surface F, disposed outward of the flat part E, to a lower inclined surface F through the end surface G is referred to as the “bevel part”.

As shown in FIG. 2, four grinding head assemblies 1A, 1B, 1C, 1D are disposed around the substrate W held by the rotationally holding mechanism 3. The tape supply and recovery mechanisms 2A, 2B, 2C, 2D are respectively disposed outward of the grinding head assemblies 1A, 1B, 1C, 1D in the radial direction, the tape supply and recovery mechanisms 2A, 2B, 2C, 2D supplying the grinding tapes 23, being grinding tools, to the grinding head assemblies 1A, 1B, 1C, 1D, and recovering the grinding tapes 23 used. The grinding head assemblies 1A, 1B, 1C, 1D are isolated from the tape supply and recovery mechanisms 2A, 2B, 2C, 2D by a partition wall 20. The space inside the partition wall 20 forms a grinding chamber 21, and the four grinding head assemblies 1A, 1B, 1C, 1D and the vacuum suction table 4 are disposed in the grinding chamber 21. In contrast, the tape supply and recovery mechanisms 2A, 2B, 2C, 2D are disposed outside the partition wall 20 (that is, outside the grinding chamber 21). The respective grinding head assemblies 1A, 1B, 1C, 1D have the same configuration, and the respective tape supply and recovery mechanisms 2A, 2B, 2C, 2D have the same configuration.

The number of grinding head assemblies and the number of tape supply and recovery mechanisms are not limited to four, and are not particularly limited.

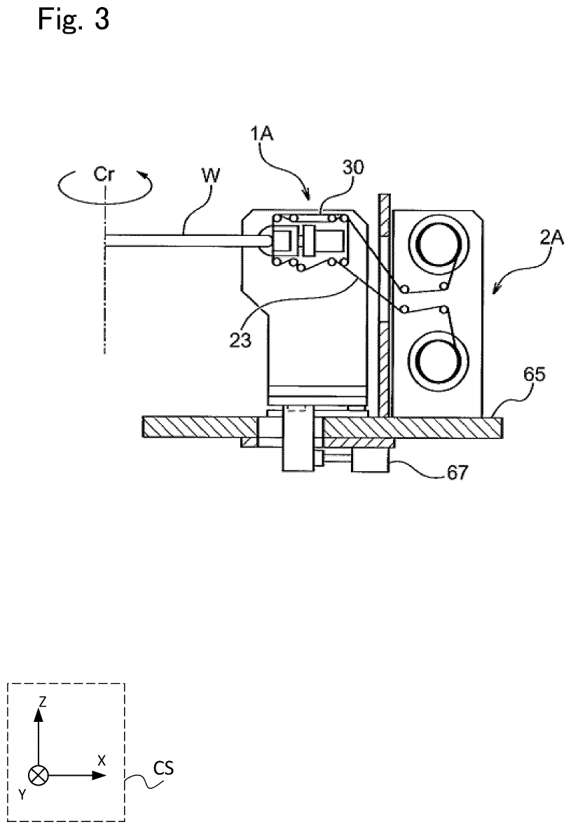

FIG. 3 is a cross-sectional view schematically showing the internal structures of the grinding head assembly 1A and the tape supply and recovery mechanism 2A. The grinding head assembly 1A includes a grinding head 30 that causes the grinding tape 23, supplied from the tape supply and recovery mechanism 2A, to be brought into contact with the peripheral edge part of the substrate W. The grinding tape 23 is supplied to the grinding head 30 such that the grinding surface of the grinding tape 23 faces the substrate W.

The grinding head 30 is fixed to one end of an arm 60 shown in FIG. 2, and the arm 60 is configured to be rotatable about an axis Ct parallel to the tangent of the substrate W. The other end of the arm 60 is coupled to a motor M4 via a pulley and a belt. When the motor M4 rotates in the clockwise or counterclockwise direction by a predetermined angle, the arm 60 rotates about the axis Ct by the predetermined angle. With such a configuration, by changing the inclination angle of the grinding head 30 according to the shape of the bevel part of the substrate W, it is possible to grind the desired position of the bevel part of the substrate W.

As shown in FIG. 3, the position of the grinding head 30 in a front-back direction (in other words, the position along the radial direction of the substrate W) can be adjusted by a linear actuator 67 that is directly or indirectly fixed to a base plate 65.

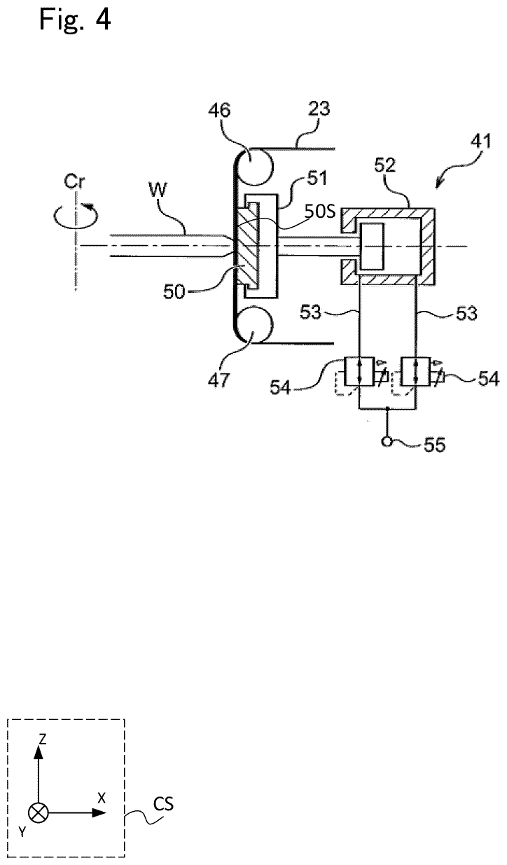

FIG. 4 is a diagram illustrating an example of a pressurizing mechanism 41 of the grinding head 30. The pressurizing mechanism 41 includes a grinding pad 50, a pad holder 51, and an air cylinder 52, the grinding pad 50 being disposed on the rear surface side of the grinding tape 23 extending between two guide rollers 46, 47 disposed at an upper portion and a lower portion on the front surface of the grinding head 30, the pad holder 51 holding the grinding pad 50, the air cylinder 52 moving the pad holder 51 toward the substrate W. The surface of the grinding pad 50 that faces the grinding tape 23 to be pressed is assumed as a grinding pad surface 50S.

The air cylinder 52 is a so-called single rod cylinder, and two air pipes 53 are connected to the air cylinder 52 via two ports. An electropneumatic regulator (solenoid valve, for example) 54 is provided at each of these air pipes 53. The primary side of the electropneumatic regulator 54 is connected to an air supply source (compressor, for example) 55, and the secondary side of the electropneumatic regulator 54 is connected to the port of the air cylinder 52. The electropneumatic regulator 54 is controlled in response to a signal from the information processor 500, and can adjust the pressure of air to be supplied to the air cylinder 52 to a desired pressure. In other words, the information processor 500 controls the electropneumatic regulator 54 such that a pressing force same as the set value input by the user can be applied. As described above, by pushing out the grinding pad 50, coupled to the piston rod of the air cylinder 52, through controlling the pressure of air to be supplied to the air cylinder 52, it is possible to control a pressure by which the grinding surface of the grinding tape 23 is pressed against the substrate W.

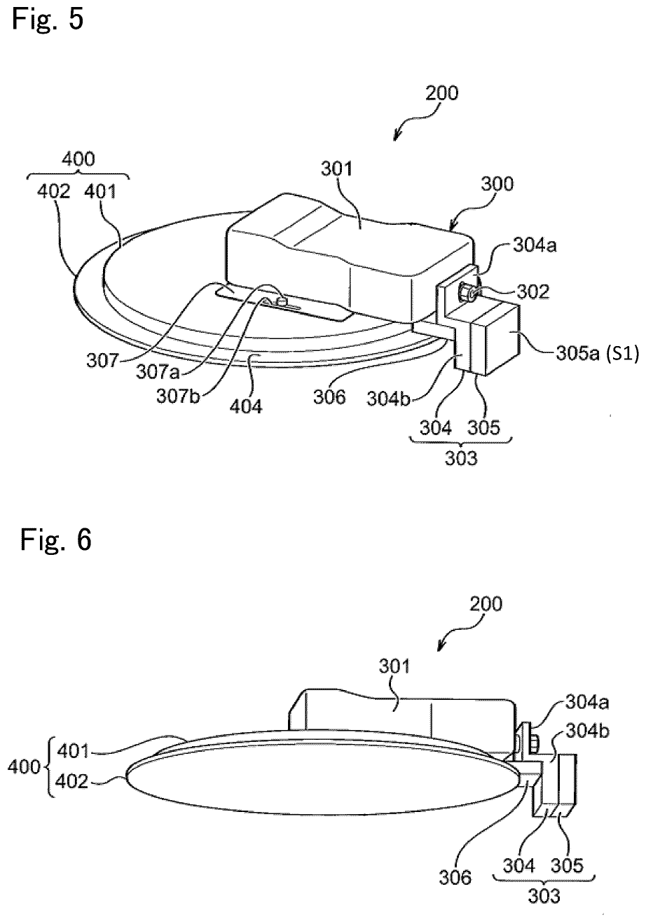

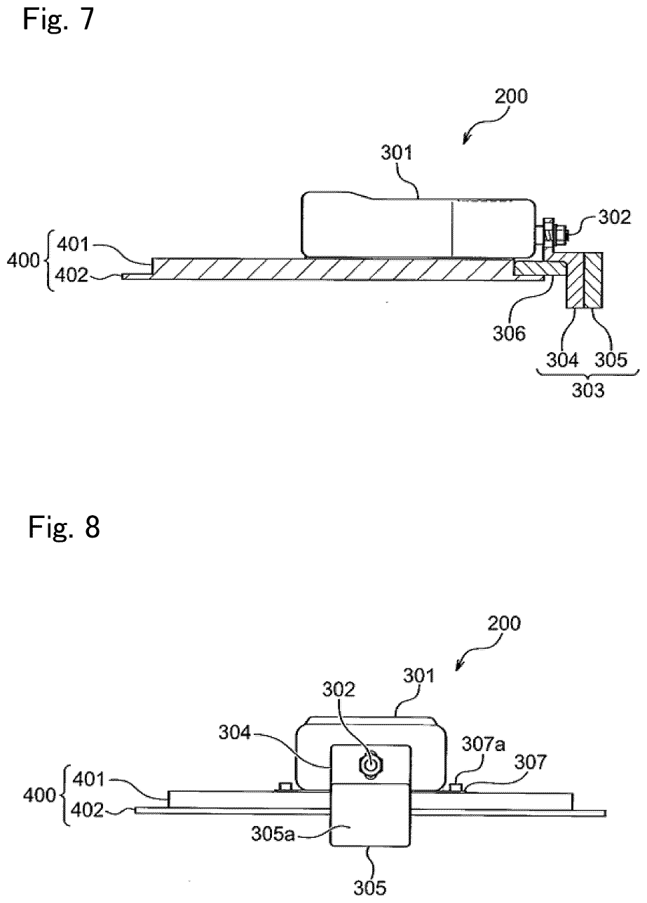

FIG. 5 is an upper perspective view of the load measuring device 200. FIG. 6 is a lower perspective view of the load measuring device 200. FIG. 7 is a side cross-sectional view of the load measuring device 200. FIG. 8 is a side view of the load measuring device 200 as viewed from the grinding head 30 side. The load measuring device 200 includes a load measuring device body 300 and a base part plate 400, the load measuring device body 300 being capable of measuring pressing load applied from the grinding pad 50 of the grinding device 100, the base part plate 400 allowing mounting of the load measuring device body 300 thereon.

The base part plate 400 can be fixed on the vacuum suction table 4 of the grinding device 100. In the example shown in the drawing, the base part plate 400 has a mode where plate-like members having a substantially circular shape and having different diameters are coaxially arranged along the up-down direction, and the base part plate 400 includes an upper plate 401 and a lower plate 402, the upper plate 401 having a small diameter, the lower plate 402 having a large diameter. The load measuring device body 300 is fixed to the base part plate 400 with a mounting plate 307 therebetween by using adjusting screws 307a and slots 307b.

The load measuring device body 300 includes a force gauge 301. Hatching on the cross section of the force gauge 301 is omitted, and the same applies for the following drawings. The force gauge 301 is placed on the upper plate 401 such that a measuring shaft 302 extending from the body of the force gauge 301 is directed in the direction toward the grinding head 30 disposed around the base part plate 400. The load measuring device body 300 may include a load support member 303 that can be fixed to the measuring shaft 302 of the force gauge 301. In the example shown in the drawing, the load support member 303 includes a bracket 304, and the bracket 304 includes a mounter 304a and a supporter 304b, the mounter 304a being mounted on the measuring shaft 302, the load supporter 304b being configured to be capable of receiving a pressing load applied from the grinding pad 50. The mounter 304a allows the bracket 304 to be fixed to the measuring shaft 302 by a combination of a bolt and a nut. The load support member 303 includes a pad 305 made of resin (PEEK, for example), and fixed to the outer side surface of the mounter 304a of the bracket 304 made of metal. The pad 305 need not be provided. The outer side surface 305a of the pad 305, or the outer side surface of the load supporter 304b provided with no pad 305 forms a load support surface S1 that is pressed by the grinding pad 50.

In the example shown in the drawing, the load measuring device 200 includes a spacer 306. The spacer 306 can be removably disposed at a stepped portion 404 formed between the upper plate portion 401 and the lower plate portion 402. It is preferable that one end portion of the spacer 306 have a shape that conforms to the outer peripheral surface of the upper plate portion 401. By causing the load supporter 304b of the bracket 304 to be brought into contact with the other end portion of the spacer 306, it is possible to adjust the position of the load support surface S1 relative to the base part plate 400, and therefore, relative to the vacuum suction table 4 to which the base part plate 400 is fixed. The mode of the load measuring device 200 is not particularly limited provided that the load measuring device 200 can perform load measurement and can send measurement data to the information processor 500.

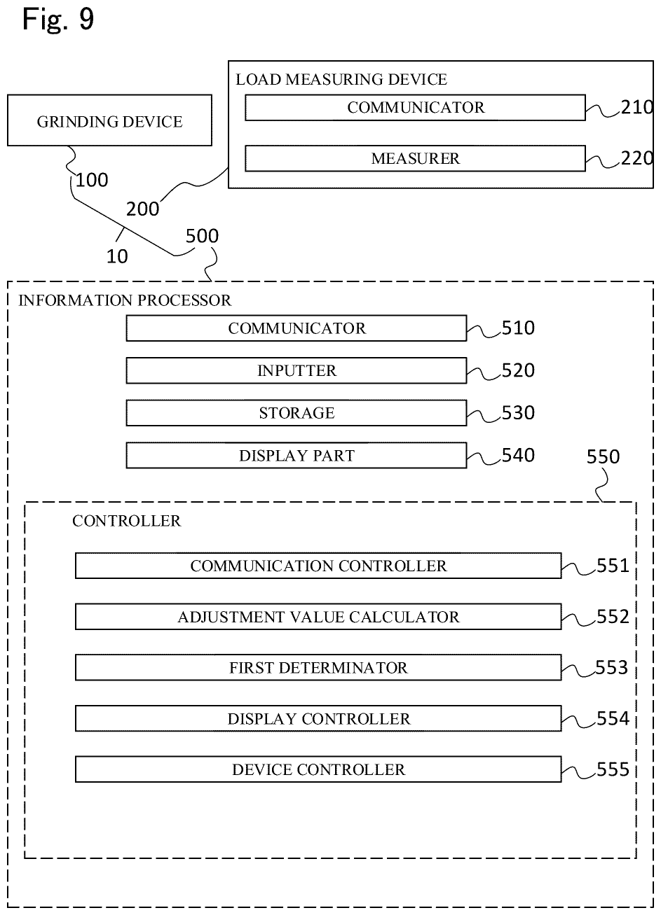

FIG. 9 is a conceptual view showing the configuration of the load adjusting system 10 of the present embodiment. The load measuring device 200 includes a communicator 210 and a measurer 220. The information processor 500 includes a communicator 510, an inputter 520, a storage 530, a display part 540, and a controller 550. The controller 550 includes a communication controller 551, an adjustment value calculator 552, a first determinator 553, a display controller 554, and a device controller 555.

The communicator 210 of the load measuring device 200 includes a communication device that is capable of communicating with at least the communicator 510 of the information processor 500 by wireless or wired connection. The communicator 210 serves as a data outputter that outputs data acquired by performing load measurement to the communicator 510 of the information processor 500. Hereinafter, data including a measured value of a load acquired by load measurement is referred to as measurement data.

The measurer 220 of the load measuring device 200 includes a load measuring instrument, such as a digital force gauge. In the example of the present embodiment, the force gauge 301 serves as the measurer 220. The measurer 220 performs load measurement, and generates measurement data including a value of a measured pressing load and the like.

The information processor 500 includes an information processor, such as a computer, and suitably serves as an interface with the user. In addition to the above, the information processor 500 performs processes on various kinds of data, such as communicating, storing, and arithmetic operations. Respective components of the information processor 500 may be disposed in devices that are physically different from each other. At least a portion of data processed by the information processor 500 may be stored in a remote server or the like. For example, a portion of control performed by the controller 550 may be performed by a programmable logic controller (PLC) that is integrally formed with the grinding device 100 or the load measuring device 200, and other functions of the information processor 500 may be mounted on a computer disposed physically separated from the PLC. In this case, for example, the communicator 510, the communication controller 551, the adjustment value calculator 552, and the device controller 555 may be disposed in the PLC, and the inputter 520, the storage 530, the display part 540, the first determinator 553, and the display controller 554 may be disposed in the computer.

The communicator 510 of the information processor 500 includes a communication device capable of communicating with at least the communicator 210 of the load measuring device 200 by wireless or wired connection. The communicator 510 serves as a data acquirer that acquires measurement data from the communicator 210 of the load measuring device 200.

The inputter 520 of the information processor 500 includes input devices, such as a mouse, a keyboard, various buttons, or a touch panel. The inputter 520 receives inputs necessary for the operation of the grinding device 100 or the load measuring device 200 from the user.

The storage 530 of the processor 500 includes a nonvolatile or volatile storage medium. The storage 530 stores, for example, measurement data, design parameters, which will be described later, and a program that causes the controller 550 to perform processes.

The display part 540 of the processor 500 includes a display device, such as a liquid crystal monitor. Information and the like acquired by performing the processes by the controller 550 are displayed on the display part 540.

The controller 550 of the information processor 500 includes a control device that includes a processor, such as a central processing unit (CPU) or a PLC. The controller 550 serves as the main controller for the operation controlling the load adjusting system 10. The controller 550 reads programs stored in the storage 530 or the like into the memory and executes the programs to perform various processes. Provided that processes can be performed by the controller 550, the physical configuration and the like of the controller 550 are not particularly limited.

The communication controller 551 of the controller 550 performs communication by controlling the communicator 510. The communication controller 551 transmits and receives necessary data, for example, receives data from the load measuring device 200 or the like.

Based on measurement data and set parameters set for the grinding head 30, the adjustment value calculator 552 of the controller 550 calculates an adjustment value used for adjusting the pressing load of the grinding head 30. In the present embodiment, the set parameter is a parameter used for causing the grinding head 30 to be operated so as to achieve a value of the set pressing load. The set parameter may be, for example, a parameter necessary to be determined in operating the pressurizing mechanism 41, such as a parameter necessary to be determined in controlling the electropneumatic regulator 54.

The adjustment value calculator 552 can calculate, as adjustment values, updated values for the set parameters from combinations of a plurality of set values for pressing load and measured values corresponding to the respective set values in measurement data. In other words, set parameters can be updated with the adjustment values. Assume that when the set value for pressing load is taken as “X”, for example, an actual pressing load Y is expressed by Y=P1*X+P2 by using design parameters P1, P2. Also assume that “N” denotes Newtons, and measurement data includes the measured value of a pressing load for which measurement is performed at the pressing load of the set value of 10 N, and the measurement data includes the measured value of a pressing load for which measurement is performed at the pressing load of the set value of 20 N. In this case, by acquiring P1 and P2 by the least squares method or the like by using a plurality of set values for pressing load and a plurality of measured values in the measurement data, it is possible to acquire updated values for the set parameters used for achieving a pressing load closer to the set value by reflecting the current state of the grinding device 100. The method for calculating the adjustment value is not limited to the case that uses the least squares method, and various modeling methods may be used.

The first determinator 553 of the controller 550 performs a first determination that determines whether the adjustment value is an appropriate value. First information showing the range of the appropriate value for the first determination is stored in advance in the storage 530 or the like. The first information may be, for example, numerical values that determine a numerical range, such as the upper limit value and the lower limit value of the appropriate value for the first determination. Appropriate values are set based on past data, theory, or the like. For example, appropriate values may be determined such that values regarded as extremely large or small are excluded, based on variations of set parameters in past data.

The display controller 554 of the controller 550 controls the display part 540 to cause the display device to perform display of information relating to the grinding head 30. This information includes at least one of information based on the measurement data or the adjustment values calculated by the adjustment value calculator 552. The information based on the measurement data may include the measured value of a pressing load, for example.

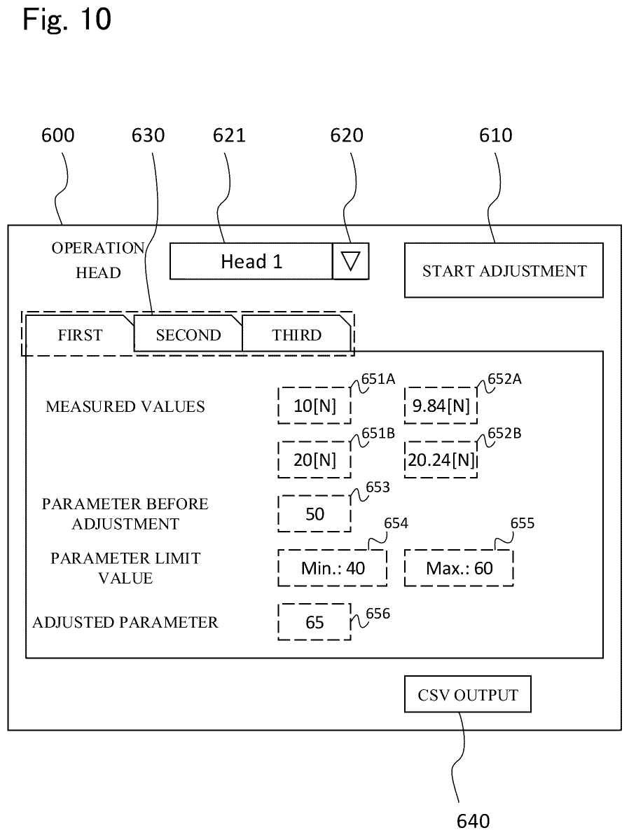

FIG. 10 is a conceptual view showing an example of a display screen including information relating to the grinding head 30. A load adjustment screen 600 includes a first screen element 610, a second screen element 620, a third screen element 630, a fourth screen element 640, a head item 621, set value items 651A, 651B, measured value items 652A, 652B, a set parameter item 653, a parameter lower limit item 654, a parameter upper limit item 655, and an adjustment value item 656. The load adjustment screen 600 is merely an example, and design and numerical values are not limited to the above provided that the measured values of load measurement or an adjusted parameter are shown.

The first screen element 610 is a screen element, such as a button, that receives inputs from the user. When the user performs inputting via the first screen element 610 by a click, a touch, or the like, load adjustment is started. The second screen element 620 is a screen element, such as a pull-down list, configured to allow the user to perform selection from a plurality of options. When the user performs inputting via the second screen element 620 by a click, a touch or the like, it is possible to select the target for load adjustment from the grinding head assemblies 1A, 1B, 1C, and 1D. The third screen element 630 is a screen element, such as a tab, that allows the user to select content to be displayed. When the user performs inputting via the third screen element 630 by a click, a touch, or the like, it is possible to selectively display the result of any one of first load adjustment, second load adjustment, and third load adjustment. Here, it is assumed that one load adjustment is performed based on load measurements performed for loads having a plurality of different set values. The number of load measurements the contents of which are displayed is not particularly limited to three shown in the drawing. The fourth screen element 640 is a screen element, such as a button, that receives inputs from the user. When the user performs inputting via the fourth screen element 610 by a click, a touch, or the like, contents of the load adjustment screen 600 are output in a predetermined data format. In the example shown in FIG. 10, a data format is a CSV (comma separated values) format. However, provided that numerical values can be shown, the data format is not particularly limited.

The load adjustment screen 600 displays, on the side of the second screen element 620, the head item 621 showing the target, selected from the grinding head assemblies 1A, 1B, 1C, and 1D, for display of the result of load adjustment on the load adjustment screen 600. The set value items 651A and 651B show set values for load in performing load measurement. In the present embodiment, an example is shown in which measurement is performed at two set values, that is, 10 N and 20 N. The measured value items 652A and 652B show the measured values of load in the load measurement. The set parameter item 653 shows the value of set parameter before adjustment. The parameter lower limit item 654 shows the lower limit of the appropriate value of load for the first determination. The parameter upper limit item 655 shows the upper limit of the appropriate value of load for the first determination. The adjustment value item 656 shows an adjustment value. Here, the adjustment value is shown as a provisional value for an adjusted parameter in the first load adjustment.

The load adjustment screen 600 shows the set values and the measured values for load measurement, the set parameters before and after adjustment, and the range of appropriate value, thus showing the result of load adjustment in such a way as to allow the user to easily understand the result.

The device controller 555 of the controller 550 controls respective components of the grinding device 100 to control a grinding operation and an adjusting operation.

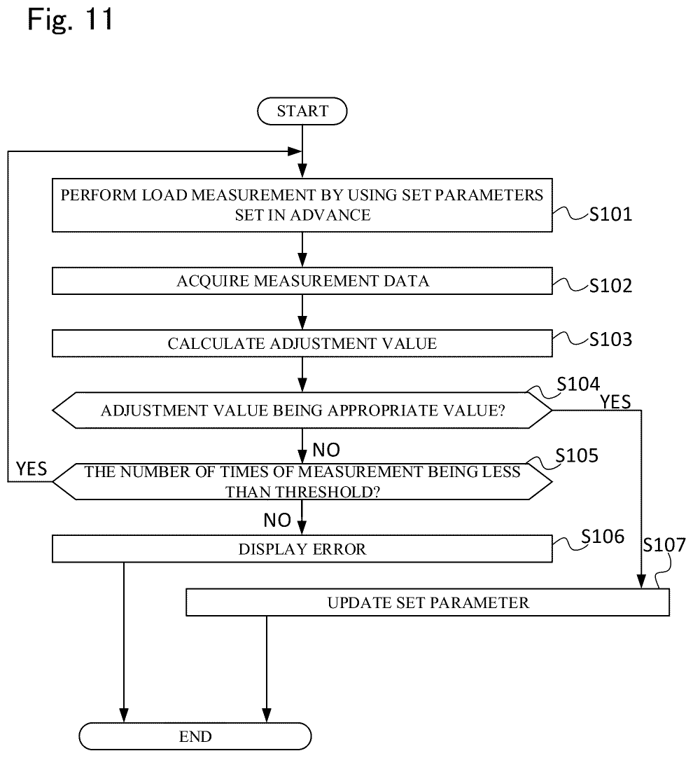

FIG. 11 is a flowchart showing the flow of a load adjusting method of the present embodiment. This load adjusting method is performed by the controller 550.

In step S101, the controller 550 performs load measurement by using set parameters set in advance. The set parameters are initial values before adjustment. Based on a set value for load input from the inputter 520 or stored in the storage 530 or the like and based on the set parameters stored in the storage 530 or the like, the device controller 555 controls a pressing operation performed by the grinding device 100. To acquire a set parameter that can achieve a more accurate load, it is preferable to perform load measurement on set values for a plurality of different loads. However, load measurement may be performed only on one set value. From the same viewpoint, it is more preferable to perform load measurement on the minimum value and the maximum value of load that may be set.

FIG. 12A and FIG. 12B are respectively a perspective view and a side view, each of which shows a use state of the load measuring device 200. Illustration of the grinding tape 23 is omitted in FIG. 12A and FIG. 12B.

For example, the rotation of the rotationally holding mechanism 3 of the grinding device 100 is stopped, the inclination angle of the grinding head 30 of each of the respective grinding head assemblies 1A, 1B, 1C, 1D is adjusted to 0 degrees (that is, to the horizontal direction as shown in FIG. 4), and the position of the grinding pad 50 in the front-back direction is adjusted to the predetermined grinding position. Next, the base part plate 400 is suctioned and fixed onto the vacuum suction table 4 such that the outer periphery of the vacuum suction table 4 aligns with the outer periphery of the base part plate 400. Thereafter, the position of the load support surface S1 of the load measuring device 300 relative to the vacuum suction table 4 is adjusted by using the spacer 306 or the like. By rotating the vacuum suction table 4, for example, adjustment can be performed such that the load support surface S1 is parallel to the grinding pad surface 50S. After the position is adjusted, a worker inputs a set value for pressing load via the inputter 520 as needed, and then clicks, for example, the first screen element 610 (FIG. 10) of the load adjustment screen 600 to operate the grinding head 30. When the load support surface S1 is pressed, the force gauge 301 of the load measuring device 200 measures a load.

Returning to FIG. 11, step S102 is performed after step S101. In step S102, the communication controller 551 controls the communicator 510 to acquire measurement data via the communicator 210 of the load measuring device 200. The communication controller 551 causes the acquired measurement data to be stored in the storage 530 or the like.

Step S103 is performed after step S102. In step S103, the adjustment value calculator 552 calculates the adjustment value from measurement data and the set parameters stored in the storage 530 or the like.

Step S104 is performed after step S103. In step S104, the first determinator 553 determines whether the adjustment value is an appropriate value. When the adjustment value is the appropriate value, the first determinator 553 makes an affirmative determination in step S104, and step S107 is started. When the adjustment value is not the appropriate value, the first determinator 553 makes a negative determination in step S104, and step S105 is started.

In step S105, the controller 550 determines whether the number of times of load measurement performed is less than a predetermined threshold. This determination is performed to prevent repetition of undesired load adjustment. When the number of times of measurement is less than the threshold, the controller 550 makes an affirmative determination in step S105, and step S101 is started. When the number of times of measurement is equal to or more than the threshold, the controller 550 makes a negative determination in step S105, and step S106 is started. Provided that the determination is performed based on the threshold, the number of times of measurement need not be “less than the threshold” and may be “equal to or less than the threshold”, and is not particularly limited. The same applies for the determination described below that uses the threshold.

In step S106, the display controller 554 displays, on the display part 540, an error indicating that the load adjustment is a failure. The display method is not particularly limited, and a message or a figure may be displayed by suitably displaying a pop-up window on a display screen. The process ends after step S106.

In step S107, the controller 550 updates the set parameter with the adjustment value. The process ends after step S107. After the load adjustment is performed, a pressing operation is performed by the device controller 555 by using a set parameter that is updated with the adjustment value.

In the adjusting system 10 and the adjusting method of the present embodiment, the communication controller 551 acquires, from the load measuring device 200 that performs measurement of a pressing load applied from the grinding head 30, measurement data acquired by performing the measurement, the adjustment value calculator 552 calculates, based on the measurement data and based on set parameters set for the grinding head 30, an adjustment value used for adjusting the pressing load, and the device controller 555 controls the pressing operation of the grinding head 30 based on the adjustment value. Consequently, it is unnecessary to perform, for example, an operation in which a worker visually reads information about pressing load, and then inputs the information into the device and hence, a working time and man-hours can be reduced, thus achieving efficient adjustment of load. Further, it is possible to reduce mistakes caused by manually inputting numerical values and hence, adjustment work can be performed more accurately.

A configuration may be adopted in which, when the calculator 552 calculates an adjustment value in step S103, the set parameter is updated with the adjustment value. In this case, in the first determination in step S104, a determination is made on whether the updated set parameter (updated parameter) is the appropriate value. The set parameter before adjustment is held in the storage 530 or the like until it is determined in step S104 that the updated parameter is the appropriate value.

The following modifications also fall within the scope of the present invention, and may be combined with the above-described embodiment or with another modification. In the following modifications, components having the same structure and function as the corresponding components in the above-described embodiment are given the same reference symbols, and the description of such components will be omitted when appropriate.

### Modification 1

In the above-described embodiment, the controller may perform load measurement again based on the adjustment value and, thereafter, may perform a second determination that determines whether the pressing load of the grinding head 30 acquired by the load measurement performed again is an appropriate value.

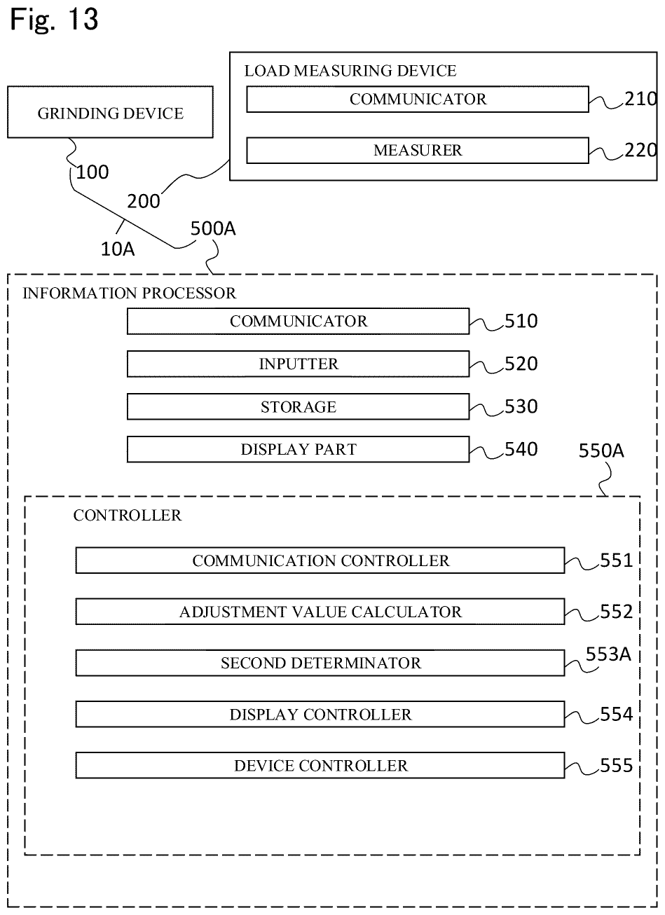

FIG. 13 is a conceptual view showing the configuration of a load adjusting system of the present modification. Although a load adjusting system 10A has a configuration similar to that of the load adjusting system 10 in the above-described embodiment, the load adjusting system 10A differs from the load adjusting system 10 in that the load adjusting system 10A includes a second determinator 553A instead of the first determinator 553. The load adjusting system 10A includes an information processor 500A, and the information processor 500A includes a controller 550A including the second determinator 553A.

The second determinator 553A performs the second determination. In the second determination, it is determined whether the measured value of a pressing load is an appropriate value in the load measurement performed again by using the adjustment value. Second information showing the range of the appropriate value for the second determination is stored in advance in the storage 530 or the like. The second information may be, for example, numerical values that determine a numerical range indicating the range of the percentage of the appropriate value for the second determination to the set value. This numerical range is set based on past data, theory, or the like. This numerical range may be determined to be, for example, from 90% to 110% based on the accuracy of the grinding device 100 or the load measuring device 200, or based on the accuracy required for the load adjustment, for example.

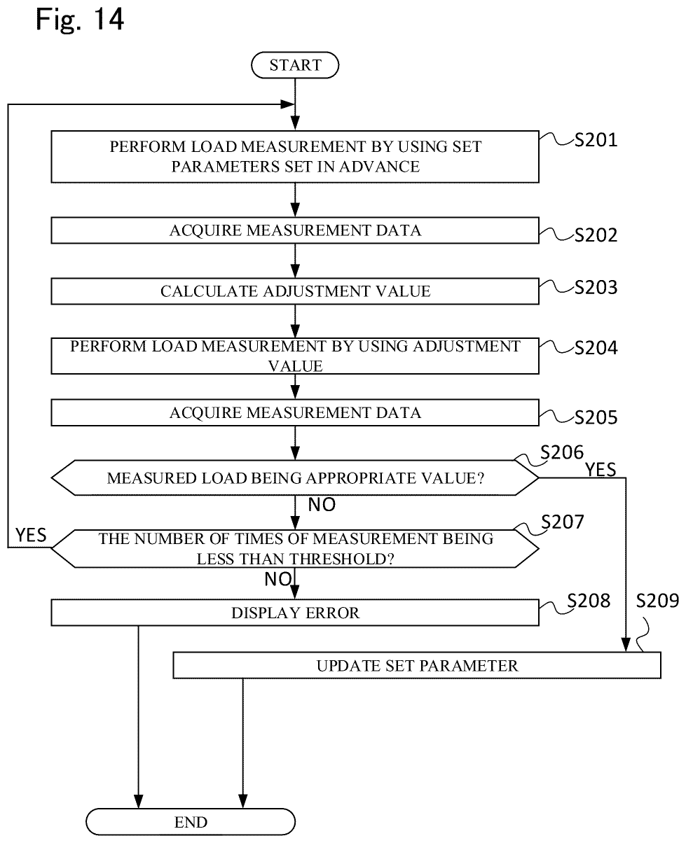

FIG. 14 is a flowchart showing the flow of a load adjusting method of the present modification. This load adjusting method is performed by the controller 550A. Steps S201 to S203 are substantially the same as steps S101 to S103 in the flowchart shown in FIG. 11 and hence, the description of such steps will be omitted.

Step S204 is performed after step S203. In step S204, the controller 550A performs load measurement again by using the adjustment value acquired in step S203. Based on the set value for load and the adjustment value, which are input from the inputter 520 or stored in the storage 530 or the like, the controller 550A controls a pressing operation performed by the grinding device 100. The set value for load may be equal to or different from the set value for load used in step S201.

Step S205 is performed after step S204. In step S205, the communication controller 551 controls the communicator 510 to acquire, via the communicator 210 of the load measuring device 200, measurement data for the load measurement performed again. The communication controller 551 causes the acquired measurement data to be stored in the storage 530 or the like.

Step S206 is performed after step S205. In step S206, the second determinator 553A determines whether the load measured in the load measurement performed again is an appropriate value. When the load is the appropriate value, the second determinator 553A makes an affirmative determination in step S206, and step S209 is started. When the load is not the appropriate value, the second determinator 553A makes a negative determination in step S206, and step S207 is started.

In step S207, the controller 550A determines whether or not the number of times of load measurement or load adjustment performed is less than the predetermined threshold. When the number of times is less than the threshold, the controller 550A makes an affirmative determination in step S207, and step S201 is started. When the number of times is equal to or more than the threshold, the controller 550A makes a negative determination in step S207, and step S208 is started. Steps S208 and S209 are substantially the same as steps S106 and S107 in the flowchart shown in FIG. 11 and hence, the description of such steps will be omitted. The process ends after steps S208 and S209.

A configuration may be adopted in which, when the calculator 552 calculates an adjustment value in step S203, the set parameter is updated with the adjustment value. In this case, in the load measurement in step S204, load measurement is performed based on the updated parameter. The set parameter before adjustment is held in the storage 530 or the like until it is determined in step S206 that the measured load is the appropriate value.

In the adjusting system 10A in the present modification, the second determinator 553A determines whether or not the pressing load of the grinding head 30 acquired in the load measurement performed again based on the adjustment value or the updated parameter is the appropriate value. Consequently, by actually performing load measurement, it is possible to confirm whether the set parameter is updated to the appropriate value.

### Modification 2

In the above-described embodiment, a configuration may be adopted in which, before load measurement is performed, an image including the load support member 303 and the grinding head 30 is photographed, and it is determined based on the image whether the load support surface S1 and the grinding pad surface 50S, which presses the load support surface S1, are sufficiently parallel to each other. Hereinafter, this image is referred to as a “determination image”, and this determination is referred to as a “third determination”.

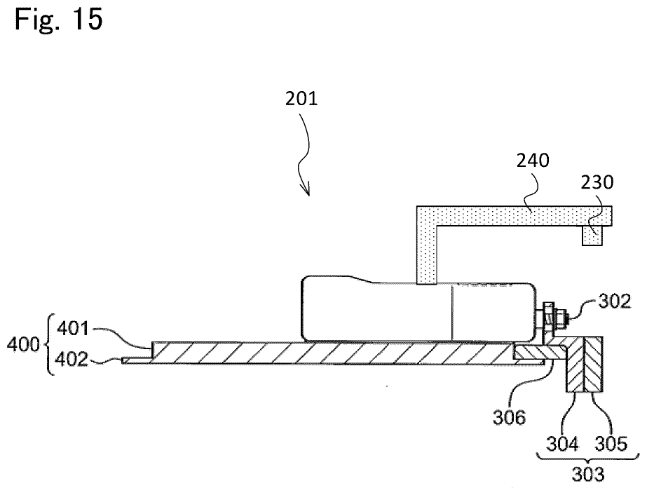

FIG. 15 is a side cross-sectional view schematically showing a load measuring device 201 in the present modification. The load measuring device 201 includes an imager 230 and an imager support member 240. The imager 230 includes an imaging device, such as a camera. In the present modification, the imager 230 is configured to acquire an image of the load support member 303 and the grinding head 30 by performing photographing in the downward vertical direction. However, provided that a parallel index, which will be described later, can be calculated, the imager 230 may perform photographing from any direction. Further, provided that the imager 230 can be fixed, the material and the shape of the imager support member 240 are not particularly limited.

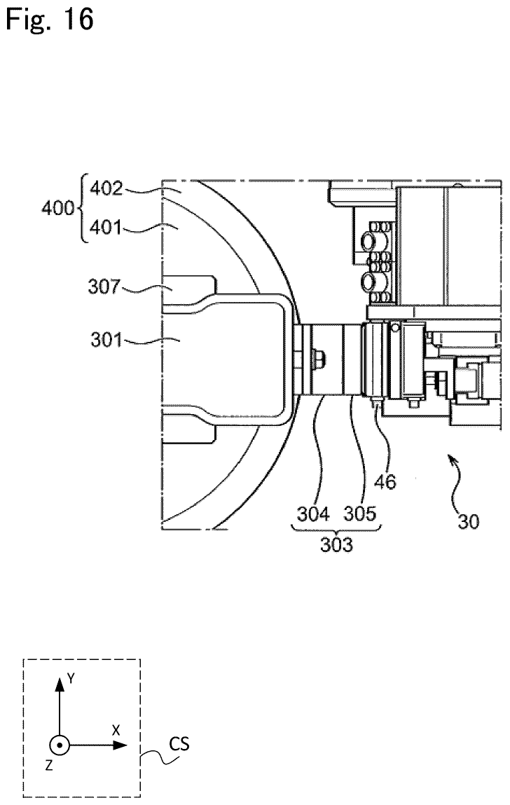

FIG. 16 is a diagram showing an example of the determination image photographed by the imager 230. In the example shown in FIG. 16, the determination image is an image including the pad 305 of the load support member 303 and a guide roller 46 disposed above the grinding pad 50 (see FIG. 4). It is preferable that, as described above, the determination image includes an image of the vicinity of a position at which the load support member 303 and the grinding head 30 come into contact with each other via the grinding tape 23 (FIG. 4) when appropriate. However, provided that the direction of the load measuring device 200 and the direction of the grinding head 30 can be calculated, objects to be photographed are not particularly limited.

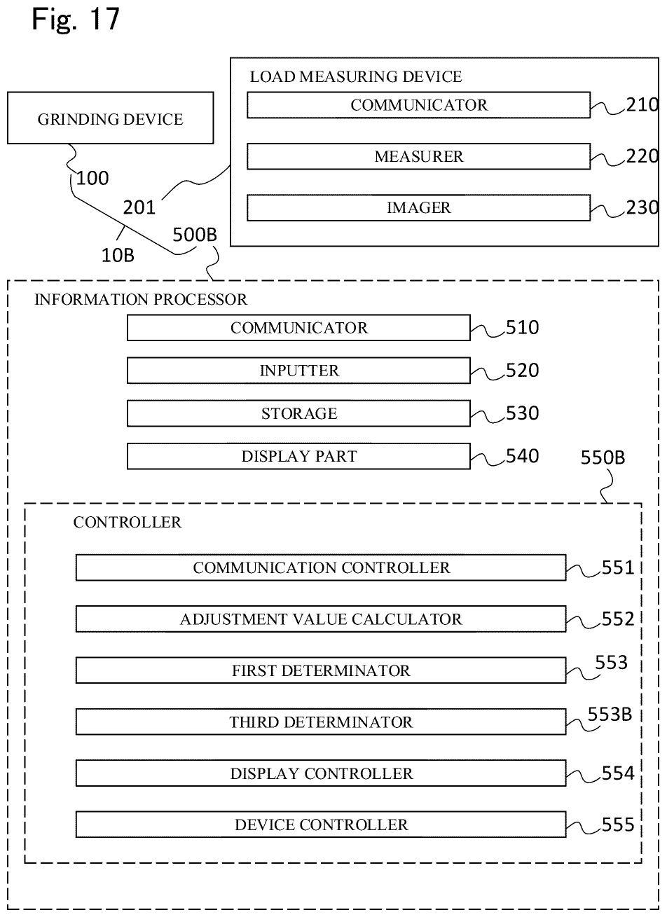

FIG. 17 is a conceptual view showing the configuration of a load adjusting system 10B in the present modification. Although the load adjusting system 10B has a configuration similar to that of the load adjusting system 10 of the above-described embodiment, the load adjusting system 10B differs from the load adjusting system 10 in that the load adjusting system 10B includes the imager 230 and a third determinator 553B. The load adjusting system 10B includes the load measuring device 201 and an information processor 500B. The load measuring device 201 includes the imager 230. The information processor 500B includes a controller 550B including the third determinator 553B.

The third determinator 553B performs the third determination. First, the communication controller 551 controls the communicator 210 of the processor 500B to acquire a determination image via the communicator 210 of the load measuring device 201. The third determinator 553B calculates, from the determination image, an index indicating the degree of parallel between the load support surface S1 and the grinding pad surface 50S by performing image processing. This index is referred to as a “parallel index”. Examples of the parallel index include the deviation amount or parallelism. The deviation amount shows the amount of deviation between the direction of the load support surface S1 and the direction of the grinding pad surface 50S. Examples of the deviation amount include an angle formed between the normal of the load support surface S1 and the normal of the grinding pad surface 50S, or an angle formed between the load support surface S1 and the grinding pad surface 50S in a predetermined cross section. The calculating method of the deviation amount is not particularly limited. For example, regarding each of the load support member 303 and the grinding head 30, the shape of the profile of a portion that appears in a determination image is stored in advance as shape data in the storage 530 or the like. The third determinator 553B extracts the profile of the load support member 303 and the profile of the grinding head 30 from the determination image by extracting feature points or the like. The third determinator 553B analyzes the extracted profiles based on the shape data, thus calculating the deviation amount between the load support surface S1 and the grinding pad surface 50S. In the case of parallelism, by approximating one of either the load support surface S1 or the grinding pad surface 50S to a reference surface, it is possible to determine the degree of inclination of the other. A mark having a characteristic shape may be formed on the load support member 303 or the grinding head 30 to facilitate the above-mentioned image processing.

Third information showing the range of an appropriate value of the parallel index for the third determination is stored in advance in the storage 530 or the like. The third information may be numerical values, such as the upper limit and the lower limit showing the allowable range of the parallel index. The appropriate value for the third determination is set based on past data, theory, or the like. The appropriate value may be determined based on the accuracy of the grinding device 100 or the load measuring device 200, or based on the accuracy required for the load adjustment, for example.

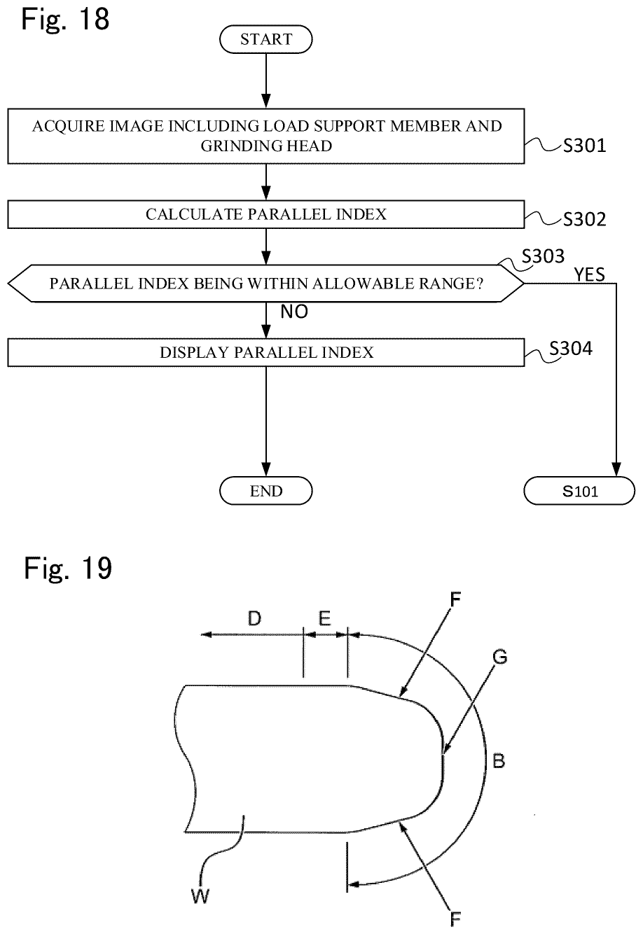

FIG. 18 is a flowchart showing the flow of a load adjusting method of the present modification. This load adjusting method is performed by the controller 550B.

In step S301, the communication controller 551 acquires a determination image including the load support member 303 and the grinding head 30 from the load measuring device 201. Step S302 is performed after step S301. In step S302, the third determinator 553B calculates the parallel index.

In step S303, the third determinator 553B performs the third determination that determines whether the parallel index is within an allowable range. When the parallel index is within the allowable range, the third determinator 553B makes an affirmative determination in step S303, and step S101 (FIG. 11) is started. When the parallel index is not within the allowable range, the third determinator 553B makes a negative determination in step S303, and step S304 is started.

In step S304, the display controller 554 displays the parallel index on the display part 540. After the user adjusts, based on the displayed parallel index, the direction of the load support member 303 or the direction of the grinding head 30 such that the parallel index falls within the allowable range, step S301 may be started again.

In the load adjusting system 10B in the present modification, before the load measurement is performed, the imager 230 photographs the determination image, including the load support member 303 and the grinding head 30, from a predetermined direction, and the third determinator 553B performs, based on the determination image, the third determination that determines whether the surface of the load support member 303 (referred to as a “first surface”) and the surface of the grinding head 30 (referred to as a “second surface”) that face each other are sufficiently parallel to each other. When the third determinator 553B determines in the third determination that the parallel index for the first surface and the second surface is the appropriate value, the device controller 555 performs a pressing operation by the grinding head 30, while when the third determinator 553B determines in the third determination that the parallel index is not the appropriate value, the display controller 554 displays the parallel index on the display part 540. Consequently, it is possible to acquire more accurate information about directions of the load support member 303 and the grinding head 30 and hence, load adjustment can be performed more accurately.

The above-described embodiment, the modification 1 and the modification 2 may be suitably combined. For example, the controller may have any combination of two or more selected from the first determinator 553, the second determinator 553A, and the third determinator 553B.

The present embodiment described above may also be described as the following modes. [Mode 1] According to mode 1, a load adjusting system is proposed. The load adjusting system includes: a bevel grinding device including a grinding head configured to grind a bevel part of a substrate; and a control device, the control device is configured to: acquire, from a load measuring device that performs measurement of a pressing load applied from the grinding head, measurement data acquired by performing the measurement; calculate, based on the measurement data and based on a set parameter set for the grinding head, an adjustment value used for adjusting the pressing load; and control a pressing operation of the grinding head based on the adjustment value. According to mode 1, it is possible to efficiently perform load adjustment for the bevel grinding device.

[Mode 2] According to mode 2, in mode 1, the control device is configured to generate an updated parameter acquired by updating the set parameter with the adjustment value. According to mode 2, it is possible to efficiently update the set parameter for the bevel grinding device.

[Mode 3] According to mode 3, in mode 2, the control device is configured to perform a first determination that determines whether or not the adjustment value or the updated parameter is an appropriate value. According to mode 3, it is possible to suppress a situation in which an undesired value is set as the set parameter for the bevel grinding device.

[Mode 4] According to mode 4, in mode 2 or 3, the control device is configured to perform a second determination that determines whether or not the pressing load of the grinding head acquired in the measurement performed again based on the adjustment value or the updated parameter is the appropriate value. According to mode 4, it is possible to confirm whether an appropriate pressing load is achieved due to the update of the set parameter based on an actual load measurement.

[Mode 5] According to mode 5, in mode 4, the control device is configured to perform the second determination based on whether or not the pressing load of the grinding head acquired in the measurement performed again based on the adjustment value or the updated parameter falls within a predetermined numerical range. According to mode 5, it is possible to more surely perform a determination based on the set numerical range.

[Mode 6] According to mode 6, in modes 1 to 5, the control device is configured to cause a display device to perform display of information relating to the grinding head, and at least one of information based on the measurement data or the adjustment value is displayed in the display. According to mode 6, it is possible to transmit information about the load adjustment to the user such that the user can easily understand the information.

[Mode 7] According to mode 7, in modes 1 to 6, the set parameter is a parameter used for operating the grinding head to achieve a value of a pressing load set in the grinding head, and the control device is configured to calculate, based on set values for a plurality of different pressing loads and a plurality of measured values of the corresponding pressing loads in the measurement, the adjustment value used for changing the set parameter such that the set parameter more accurately achieves a value of a pressing load set in the grinding head. According to mode 7, it is possible to perform load adjustment for the bevel grinding device more accurately.

[Mode 8] According to mode 8, in modes 1 to 7, the load adjusting system further includes: an imaging device; and the load measuring device, the load measuring device includes a support member that is brought into contact with the grinding head, thus receiving the pressing load, before the measurement is performed, the imaging device photographs an image from a predetermined direction, the image including the support member and the grinding head, the control device is configured to: perform, based on the image, a third determination that determines whether a first surface of the support member and a second surface of the grinding head are sufficiently parallel to each other, the first surface and the second surface facing each other; perform a pressing operation by the grinding head when the control device determines in the third determination that an index indicating a degree of parallel between the first surface and the second surface is an appropriate value; and cause the display device to display the index when the control device determines that the index is not the appropriate value. According to mode 8, it is possible to prevent a situation in which load measurement is performed in the case where the positions of the load measuring device and the grinding head are not appropriate and hence, it is possible to perform load adjustment more accurately.

[Mode 9] According to mode 9, a load adjusting method for a bevel grinding device is proposed. The load adjusting method includes: acquiring, from a load measuring device that performs measurement of a pressing load applied from a grinding head, measurement data acquired by performing the measurement; calculating, based on the measurement data and based on a set parameter set for the grinding head, an adjustment value used for adjusting the pressing load; and controlling a pressing operation of the grinding head based on the adjustment value, the acquiring, the calculating, and the controlling being performed by a control device configured to control the grinding device including the grinding head configured to grind a bevel part of a substrate. According to mode 9, it is possible to perform load adjustment for the bevel grinding device more efficiently.

Although the embodiments of the present invention have been described above based on some examples, the described embodiments are for the purpose of facilitating the understanding of the present invention and are not intended to limit the present invention. The present invention may be modified and improved without departing from the spirit thereof, and the invention includes equivalents thereof. In addition, the elements described in the claims and the specification can be arbitrarily combined or omitted within a range in which the above-mentioned problems are at least partially solved, or within a range in which at least a part of the advantages is achieved.

This application claims priority under the Paris Convention to Japanese Patent Application No. 2021-183206 filed on Nov. 10, 2021. The entire disclosure of Japanese Patent Application No. 2021-183206 filed on Nov. 10, 2021 including specification, claims, drawings and summary is incorporated herein by reference in its entirety. The entire disclosure of Japanese Patent Application Publication No. 2017-94480 (PTL 1) including specification, claims, drawings and summary is incorporated herein by reference in its entirety.

### REFERENCE SIGNS LIST

3 rotationally holding mechanism
4 vacuum suction table
1A, 1B, 1C, 1D grinding head assembly
2A, 2B, 2C, 2D tape supply and recovery mechanism
10, 10A, 10B load adjusting system
20 partition wall
21 grinding chamber
23 grinding tape
30 grinding head
41 pressurizing mechanism
46, 47 guide roller
50 grinding pad
50S grinding pad surface
52 air cylinder
53 air pipe
54 electropneumatic regulator
55 air supply source
100 grinding device
200, 201 load measuring device
210 communicator of load measuring device
220 measurer of load measuring device
230 imager
240 load support member
300 load measuring device body
301 force gauge
302 measuring shaft
303 load support member
304 bracket
304a mounter
304b load supporter
305 pad
400 base part plate
500, 500A, 500B information processor
510 communicator of information processor
520 inputter
530 storage
540 display part
550, 550A, 550B controller
551 communication controller
552 adjustment value controller
553 first determinator
553A second determinator
553B third determinator
554 display controller
555 device controller
600 load adjustment screen
B bevel part
Cr, Ct axis
M3, M4 motor
S1 load support surface
W substrate

1. A load adjusting system comprising: a bevel grinding device comprising a grinding head configured to grind a bevel part of a substrate; and a control device, wherein
the control device is configured to:
acquire, from a load measuring device that performs measurement of a pressing load applied from the grinding head, measurement data acquired by performing the measurement;
calculate, based on the measurement data and based on a set parameter set for the grinding head, an adjustment value used for adjusting the pressing load; and
control a pressing operation of the grinding head based on the adjustment value.

2. The load adjusting system according to claim 1, wherein the control device is configured to generate an updated parameter acquired by updating the set parameter with the adjustment value.

3. The load adjusting system according to claim 2, wherein the control device is configured to perform a first determination that determines whether or not the adjustment value or the updated parameter is an appropriate value.

4. The load adjusting system according to claim 2, wherein the control device is configured to perform a second determination that determines whether or not the pressing load of the grinding head acquired in the measurement performed again based on the adjustment value or the updated parameter is the appropriate value.

5. The load adjusting system according to claim 4, wherein the control device is configured to perform the second determination based on whether or not the pressing load of the grinding head acquired in the measurement performed again based on the adjustment value or the updated parameter falls within a predetermined numerical range.

6. The load adjusting system according to claim 1, wherein the control device is configured to cause a display device to perform display of information relating to the grinding head, and
at least one of information based on the measurement data or the adjustment value is displayed in the display.

7. The load adjusting system according to claim 1, wherein the set parameter is a parameter used for operating the grinding head to achieve a value of a pressing load set for the grinding head, and
the control device is configured to calculate, based on set values for a plurality of different pressing loads and a plurality of measured values corresponding to the set values in the measurement, the adjustment value used for changing the set parameter such that the set parameter more accurately achieves the value of the pressing load set in the grinding head.

8. The load adjusting system according to claim 1, further comprising: an imaging device; and the load measuring device, wherein
the load measuring device includes a support member that is brought into contact with the grinding head, thus receiving the pressing load,
before the measurement is performed, the imaging device photographs an image from a predetermined direction, the image including the support member and the grinding head,
the control device is configured to:
perform, based on the image, a third determination that determines whether a first surface of the support member and a second surface of the grinding head are sufficiently parallel to each other, the first surface and the second surface facing each other;
perform a pressing operation by the grinding head when the control device determines in the third determination that an index indicating a degree of parallel between the first surface and the second surface is an appropriate value; and
cause a display device to display the index when the control device determines that the index is not the appropriate value.

9. A load adjusting method for a bevel grinding device, the load adjusting method comprising:
acquiring, from a load measuring device that performs measurement of a pressing load applied from a grinding head, measurement data acquired by performing the measurement;
calculating, based on the measurement data and based on a set parameter set for the grinding head, an adjustment value used for adjusting the pressing load; and
controlling a pressing operation of the grinding head based on the adjustment value,
the acquiring, the calculating, and the controlling being performed by a control device configured to control the bevel grinding device comprising the grinding head configured to grind a bevel part of a substrate.
